(19) United States
(12) Patent Application Publication
(10) Pub. No.: US 2005/0077578 A1
(43) Pub. Date: Apr. 14, 2005

(54) Arrangement for reducing current density in transistor in an IC

(75) Inventors: Andrej Litwin, Danderyd (SE); David Andersson, Norrkoping (SE)

Correspondence Address: Andreas Grubert;Baker Botts L.L.P., One Shell Plaza, 910 Louisiana, Houston, TX, 77002-4995, US

(73) Assignee: Infineon Technologies AG

(21) Appl. No.: 11/002,018

(22) Filed: Dec. 2, 2004

Related U.S. Application Data
(63) Continuation of application No. PCT/SE03/00741, filed on May 7, 2003.

(30) Foreign Application Priority Data
Jun. 3, 2002 (SE) 0201707-7

(51) Int. Cl. H01L 23/62

(52) U.S. Cl. 257/355

(57) ABSTRACT

To reduce current density in a transistor in an IC comprising a plurality of interdigitated drain, source and gate fingers (10, 11, 12) a first current distributing plate (1) is part of a metal layer of the IC and is connected by first vias (5) to all drain fingers (10) and a second current distributing plate (2) is also part of the metal layer of the IC and is connected by second vias (6) to all source fingers (11).

### CROSS REFERENCE TO RELATED APPLICATIONS

This application is a continuation of copending International Application No. PCT/SE03/00741 filed May 7, 2003 which designates the United States, and claims priority to Swedish application no. 0201707-7 filed Jun. 3, 2002.

### TECHNICAL FIELD OF THE INVENTION

The present invention relates to power transistors in general and more specifically to an arrangement for reduction of current density in such a transistor in an integrated circuit.

### BACKGROUND OF THE INVENTION

Power transistors in the past have been especially designed to deliver high output power and high gain. Manufacturing processes, device parameters, layouts and packages have been carefully tuned for this purpose. The power transistors need to meet numerous detailed requirements for breakdown voltages, DC gain or transconductance, capacitances, RF gain, ruggedness, noise figure, input/output impedance, distortion etc. The operating frequencies range from several hundred MHz up into the microwave region.

Normally, the power transistors have been designed as multifinger devices, which is especially advantageous in the case of power transistors comprising MOS transistors. In these cases the power transistors consist of interdigitated structures of drain, source and gate areas. Each drain area is adjacent to two gate areas and collects the current from two source areas. On top of each drain, source and gate area so-called drain, source and gate fingers are located. Each such finger comprises an interconnected multi layered structure of different metals that collects the current from the active area beneath i.e. drain, source and gate areas. Such design reduces parasitic drain-to-substrate capacitance and improves HF performance of the power transistors.

However, there is a disadvantage when power transistors are made in an IC technology with feature sizes smaller than 1 μm. The reduced drain and source areas make the possible drain and source fingers narrower. At the same time the saturation current increases in more downscaled technologies up to a range of 1 mA/μm gate width. For a transistor with a gate width of 10 um that increase will result in a maximum drain and source current of 20 mA. In previous art the metal fingers connected to the source and drain areas run along the whole width of the transistor, i.e. the length of each drain or source area. Thus, each finger collects its current along the whole width of the transistor. As a consequence the current in the drain and source fingers reaches maximum in places where the finger leaves the transistor and connects to a bus bar. Due to the small dimensions of the fingers, in the order of 1 μm, the current density easily exceeds the maximum value allowed by reliability design rules even if several interconnect layers are stacked on top of each other. This puts severe limits on the operation range of the transistor.

Thus there is a need for a robust solution that reduces the current density in the drain and source fingers and by doing so increases the maximum output power from the transistor i.e. increases the operating range of the transistor.

### SUMMARY OF THE INVENTION

The object of the invention is to provide an arrangement for improving the current handling properties of the drain and source fingers in a power transistor in an IC.

The object of the invention can be achieved by providing two current distributing elements or plates on top of a power transistor or other multifingered device, wherein the elements are part of a metal layer of the IC, and each such current distributing element covers approximately half of the transistor width. The first current distributing element is connected by vias to all drain fingers along approximately half of the length, i.e. transistor width, of each drain finger. The second current distributing element is similarly connected by vias to all source fingers along approximately half of the length of each source finger, i.e. transistor width.

The maximum current collected in this manner in the drain and source fingers, respectively, before it is distributed in the arrangement according to the invention, is thus only half in comparison to the conventional design, where the current is collected and flows along the whole length of each finger.

Such an arrangement according to the invention reduces the current density in each of the fingers, both drain and source, and makes it possible to substantially increase the maximum allowed current in the entire transistor and by doing so also increasing the maximum output power.

Another advantage of the present invention is that it opens up a possibility to further decrease the dimensions of features such as the length of drain and source interconnect areas of a power transistor in an IC, without violating the so called minimum design rule for the current density. Thus, smaller and even more powerful transistors can be manufactured and more components can be provided on an IC.

### BRIEF DESCRIPTION OF THE DRAWING

An embodiment of the invention will be described more in detail below with reference to the appended drawing in which

FIG. 1 is a schematic top view of a transistor with current distributing elements according to the invention,

FIG. 2a is a schematic cross-section along line a-a in FIG. 1, and

FIG. 2b is a schematic cross-section along line b-b in FIG. 1.

### DESCRIPTION OF THE INVENTION

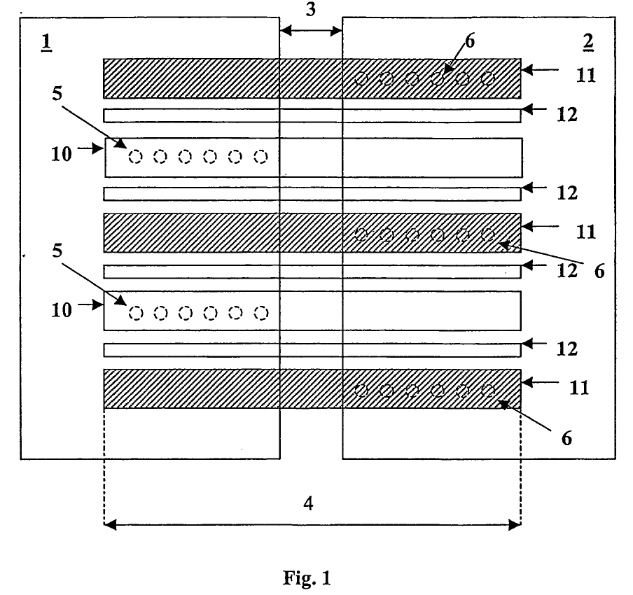

FIG. 1 is a schematic top view of a power metal oxide semiconductor field effect transistor (power MOSFET) in an IC with two current distributing elements 1, 2 according to the invention.

In a manner known per se the power MOSFET comprises a plurality of interdigitated drain, source and gate areas on top of which are located so called drain, source and gate fingers 10, 11, 12. In this structure each drain finger 10 is adjacent to two gate fingers 12 and collects the current from two source fingers 11.

The two current distributing elements, according to the invention, in the form of two current distributing conductive plates 1, 2 are provided on top of the power MOSFET as parts of a metal layer of the IC. Each plate 1, 2 is oriented in such a manner that it extends across every drain, source and gate finger 10, 11, 12 as well as the space in between each finger 10, 11, 12.

Preferably, the current distributing plates 1, 2 are coplanar and disposed so as to be separated by a predetermined distance 3, thus never overlapping each other. As a result, the plates 1, 2 together with the separating distance 3 extend along the whole transistor width 4. The transistor width 4 is defined as the length of the individual drain and source fingers 10, 11.

The separating distance 3 is determined by what is commonly known as the minimum design rule for the IC manufacturing process. Thus, the distance 3 can vary from one embodiment of the invention to another. Depending on the requirements for each specific embodiment the distance 3 can vary in the interval 50 nm to 5 μm.

Preferably, the two current distributing plates 1, 2 overlap close to equal fractions or portions of the transistor width 4. Preferably those portions are close to half the transistor width 4.

It is understood that the two plates 1, 2 can overlap also non-equal portions of the transistor width 4. Preferentially, the two plates 1, 2 should each overlap more than ⅓ of the transistor width 4 and less than ⅔ of the transistor width 4. Due to the predetermined separating distance 3 the two plates 1, 2 cannot simultaneously overlap the transistor with close to ⅔ of the transistor width 4.

The first plate 1, according to the invention, is connected by first vias 5 to all drain fingers 10. These first vias 5 are distributed along close to half the length of each drain finger 10. The second plate 2, according to the invention, is connected by second vias 6 to all or source fingers 11. Similarly, these second vias 6 are distributed along close to half the length of each source finger 11.

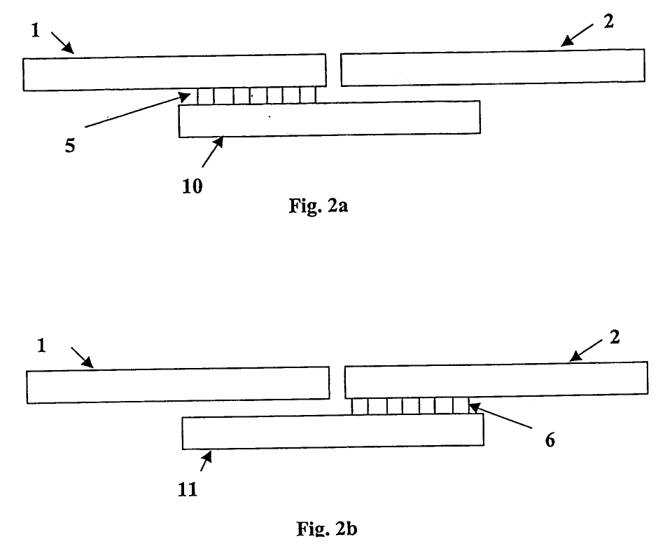

As better shown in FIG. 2a, the first plate 1 is located on top of the drain finger 10 and is connected to it, while the second plate 2 is located on top of the drain finger 10 but not connected to it.

Similarly, as better shown in FIG. 2b, the second plate 2 is located on top of the source finger 11 and connected to it, while the first plate 1 is located on top of the source finger 11 but not connected to it.

It is understood that the first and second vias 5, 6 can be located along more than half the finger length as well as along less than half the finger length, dependent of the fraction or portion of the transistor width 4 that is covered by each of the aforementioned two plates 1, 2.

Preferably, the current distributing elements 1, 2 are rectangular plates. It is nonetheless understood that both the shape and the size of the current distributing elements 1, 2 can be different.

There may be other varieties of the layout of the current distributing elements 1, 2 where the width of the source and drain current distributing element 1, 2 respectively can vary, dependent of the maximum current density in drain and source fingers 10, 11 respectively. The layout is also decided by the desired total output current from the source and drain fingers 10, 11 respectively.

The plates 1, 2 can be made substantially of either aluminum, copper or gold. In the case of aluminum the material is usually alloyed with copper and/or titanium and/or other alloying elements. Similarly for the case of gold and copper the material can be alloyed with different alloying elements in order to achieve the desired properties. Also other conductive materials can be utilized dependent of the desired properties of the arrangement.

The manufacture of the plates 1, 2 can be performed by means of electroplating, sputtering, vapor deposition or some other deposition technique. In order to achieve good adhesion to the transistor the plates 1, 2 are formed by layering different materials, especially in the case of copper plates. Usually, depositing an adhesive layer or a barrier layer precedes the deposit of the plates 1, 2 on the top of the transistor. In order to define the areas of the IC that are to be provided with the plates 1, 2 a mask is provided in a known manner on the IC before manufacture of the plates 1,2.

The embodiment according to the invention relates to the reduction of current density in a power MOSFET in an IC. It is understood that a similar arrangement can be applied to other types of transistors e.g. bipolar. The invention is not restricted to HF use.

It is obviously understood that the present invention is not limited to the preferred embodiment, but can be modified within the limits of the appended claims.

1. An arrangement for reduction of current density in a transistor in an IC, said transistor comprising a plurality of interdigitated drain, source and gate fingers, wherein a first current distributing plate is located on top of the transistor and is part of a metal layer of the IC and is connected to all drain fingers by first vias and a second current distributing plate, that is coplanar with said first plate, is located on top of the transistor and is part of the metal layer of the IC and is connected to all source fingers by second vias.

2. The arrangement according to claim 1, wherein the first and second current distributing plates are separated by a predetermined distance.

3. The arrangement according to claim 2, wherein said distance is in the interval 50 nm to 5 μm.

4. The arrangement according to claim 1, wherein said first current distributing plate overlaps a first predetermined portion of the transistor width and said second current distributing plate overlaps a second predetermined portion of the transistor width.

5. The arrangement according to claim 1, wherein said two current distributing plates (1, 2) and said separating distance together extend along the whole transistor width.

6. The arrangement according to claim 2, wherein said two current distributing plates (1, 2) and said separating distance together extend along the whole transistor width.

7. The arrangement according to claim 4, wherein said first portion of the transistor width is equal to between ⅓ and ⅔ of the transistor width and said second portion of the transistor width is equal to between ⅔ and 1/3 of the transistor width.

8. The arrangement according to claim 4, wherein said first and second portions of the transistor width are equal.

9. The arrangement according to claim 1, wherein said current distributing plates (1, 2) are made substantially of aluminum, copper or gold.

10. A method for reduction of current density in a transistor in an IC, comprising the steps of:
providing a transistor comprising a plurality of interdigitated drain, source and gate fingers,
arranging a first current distributing plate on top of the transistor which is part of a metal layer of the IC,
connecting said distributing plate to all drain fingers by first vias, and
arranging a second current distributing plate coplanar with said first plate on top of the transistor which is part of the metal layer of the IC, and
connecting said second current distributing plate to all source fingers by second vias.

11. The method according to claim 10, wherein the first and second current distributing plates are separated by a predetermined distance.

12. The method according to claim 11, wherein said distance is in the interval 50 nm to 5 μm.

13. The method according to claim 10, wherein said first current distributing plate overlaps a first predetermined portion of the transistor width and said second current distributing plate overlaps a second predetermined portion of the transistor width.

14. The method according to claim 10, wherein said two current distributing plates (1, 2) and said separating distance together extend along the whole transistor width.

15. The method according to claim 11, wherein said two current distributing plates (1, 2) and said separating distance together extend along the whole transistor width.

16. The method according to claim 13, wherein said first portion of the transistor width is equal to between ⅓ and ⅔ of the transistor width and said second portion of the transistor width is equal to between ⅔ and ⅓ of the transistor width.

17. The method according to claim 13, wherein said first and second portions of the transistor width are equal.

18. The method according to claim 10, wherein said current distributing plates (1, 2) are made substantially of aluminum, copper or gold.
